(19) United States
(12) Patent Application Publication
(10) Pub. No.: US 2026/0005104 A1
(43) Pub. Date: Jan. 1, 2026

(54) HEAT DISSIPATION STRUCTURE AND SEMICONDUCTOR PACKAGE DEVICE

(71) Applicant: JCET MANAGEMENT CO., LTD, Shanghai (CN)

(72) Inventors: Yiqian LUO, Shanghai (CN); Hua ZONG, Shanghai (CN); Jingcheng GE, Shanghai (CN); Shuo LIU, Shanghai (CN)

(73) Assignee: JCET MANAGEMENT CO., LTD, Shanghai (CN)

(21) Appl. No.: 19/248,390

(22) Filed: Jun. 24, 2025

(30) Foreign Application Priority Data
Jun. 28, 2024 (CN) 202410854037.4

(51) Int. Cl. H01L 23/473

(52) U.S. Cl. CPC H01L 23/473

(57) ABSTRACT

The present disclosure relates to a heat dissipation structure and a semiconductor package device. The heat dissipation structure includes: a top cover, including an inner surface and an outer surface that are oppositely disposed; a heat dissipation hole, at least partially disposed within the top cover, the heat dissipation hole including an inlet disposed within the top cover and an outlet exposed at the outer surface, wherein an aperture of the outlet is greater than an aperture of the inlet; and a heat dissipation channel, including a first heat dissipation channel disposed within the top cover and extending through the top cover in a direction parallel to the outer surface, wherein the first heat dissipation channel is in communication with the inlet and is configured to transfer heated fluid to the inlet. The heat dissipation structure according to the present disclosure enhances the heat dissipation effect.

### CROSS-REFERENCE TO RELATED APPLICATION

This application claims priority of Chinese Patent Application No. 202410854037.4, filed Jun. 28, 2024, entitled as “HEAT DISSIPATION STRUCTURE AND SEMICONDUCTOR PACKAGE DEVICE,” the entire disclosure of which is incorporated herein by reference for all purposes.

### TECHNICAL FIELD

The present disclosure relates to the technical field of integrated circuits, and in particular, relates to a heat dissipation structure and a semiconductor package device.

### BACKGROUND

Since the 20th century, chip manufacturing processes have become increasingly sophisticated. With the advancement of technology, the level of integration of chips has undergone a dramatic transformation—from thousands of transistors in the early chips to tens of billions or even more in modern chips. During operation, the transistors within a chip generate a significant amount of heat. If the heat is not effectively dissipated, the chip may overheat, leading to degraded performance or even permanent damage. Accordingly, effective heat dissipation for chips is of critical importance. At present, mainstream chip cooling solutions primarily rely on the attachment of heat sinks or heat spreaders, which are typically made of metal materials with favorable thermal conductivity. The heat sink or heat spreader is adhered to the surface of the chip using a thermally conductive adhesive. During operation, the heat generated by the chip is transferred to the heat sink or heat spreader, and subsequently dissipated into the ambient air through direct contact between the heat sink or heat spreader and the surrounding environment, such that the chip is cooled. Currently, in order to enhance the heat dissipation performance, a common approach is to increase the surface area of the heat sink or heat spreader in contact with the air. However, even with an increased surface area of the heat sink or heat spreader in contact with air, some limitations still exist in terms of heat dissipation for semiconductor package devices. As the number of chips integrated within semiconductor package devices continues to increase, the impact of heat dissipation on the overall device performance becomes more pronounced.

Accordingly, how to enhance the heat dissipation performance of semiconductor package devices, reduce heat accumulation within the device, and thereby improve performance and ensure continuous and stable operation of the semiconductor package device, has become an urgent technical challenge to be addressed.

### SUMMARY

The present disclosure provides a heat dissipation structure and a semiconductor package device, which are intended to enhance the heat dissipation performance of the semiconductor packaging device, and reduce heat accumulation within the device, thereby improving the overall performance of the semiconductor packaging device and ensuring its continuous and stable operation.

Some embodiments of the present disclosure provide a heat dissipation structure. The heat dissipation structure includes: a top cover, including an inner surface and an outer surface that are oppositely disposed; a heat dissipation hole, at least partially disposed within the top cover, the heat dissipation hole including an inlet disposed within the top cover and an outlet exposed at the outer surface, wherein an aperture of the outlet is greater than an aperture of the inlet; and a heat dissipation channel, including a first heat dissipation channel disposed within the top cover and extending through the top cover in a direction parallel to the outer surface, wherein the first heat dissipation channel is in communication with the inlet and is configured to transfer heated fluid to the inlet.

In some embodiments, the top cover includes a first region and a second region peripherally disposed around the first region; and the heat dissipation hole includes: a plurality of first heat dissipation holes uniformly distributed within the first region of the top cover, each of the first heat dissipation holes including a first inlet disposed within the top cover and a first outlet exposed at the outer surface, wherein an aperture of the first outlet is greater than an aperture of the first inlet.

In some embodiments, the heat dissipation hole further includes: a plurality of second heat dissipation holes disposed within the second region of the top cover, each of the second heat dissipation holes including a second inlet disposed within the top cover and a second outlet exposed at the outer surface, wherein an aperture of the second outlet is greater than an aperture of the second inlet, and the second heat dissipation holes on opposite sides of the first region are arranged in a staggered manner.

In some embodiments, the aperture of the second inlet of the second heat dissipation hole is greater than the aperture of the first inlet of the first heat dissipation hole, and the aperture of the second outlet of the second heat dissipation hole is greater than the aperture of the first outlet of the first heat dissipation hole.

In some embodiments, the first heat dissipation channel includes a first opening and a second opening that are oppositely distributed in a first direction, the first direction being perpendicular to the outer surface; wherein the first opening is in communication with the second inlet of the second heat dissipation hole, and an aperture of the first opening is greater than an aperture of the second opening.

In some embodiments, the heat dissipation channel further includes: a second heat dissipation channel, at least partially disposed within the top cover, the second heat dissipation channel extending in the first direction and being in communication with the second opening, wherein an inner diameter of the second heat dissipation channel progressively decreases along the first direction.

In some embodiments, the heat dissipation structure further includes: a side plate, connected to an end portion of the top cover, and connected to the top cover either perpendicularly or at an inclined angle, wherein the side plate and the top cover together form an accommodation chamber; wherein the heat dissipation channel further includes a third heat dissipation channel disposed within the side plate, the third heat dissipation channel including a third opening and a fourth opening, wherein the third opening is in communication with the second heat dissipation channel, and the fourth opening is disposed in a surface of the side plate facing the accommodation chamber.

In some embodiments, the heat dissipation channel further includes: a fourth heat dissipation channel, disposed within the side plate and extending through the side plate in a direction parallel to the outer surface; wherein in the first direction, the third heat dissipation channel is positioned above the fourth heat dissipation channel.

In some embodiments, the heat dissipation channel further includes: a fifth heat dissipation channel, disposed within the side plate and extending through the side plate in a direction parallel to the outer surface; wherein in the first direction, the fifth heat dissipation channel is positioned below the fourth heat dissipation channel.

In some embodiments, the fifth heat dissipation channel includes a cooling fluid inlet and a cooling fluid outlet that are oppositely distributed, the cooling fluid inlet being disposed in a surface of the side plate facing away from the accommodation chamber, and the cooling fluid outlet being disposed in a surface of the side plate facing toward the accommodation chamber; wherein in the first direction, the cooling fluid inlet is positioned above the cooling fluid outlet.

In some embodiments, the fifth heat dissipation channel includes a first portion extending in a direction parallel to the outer surface and a second portion that is in inclined communication with the first portion; wherein the cooling fluid inlet is disposed at an end of the first portion facing away from the second portion, and the cooling fluid outlet is disposed at an end of the second portion facing away from the first portion.

In some embodiments, the plurality of the first heat dissipation holes are arranged in an array along a second direction and a third direction, the second direction and the third direction being parallel to the outer surface, and the second direction being intersected with the third direction; wherein at least a portion of the first heat dissipation channels extend along the second direction and are spaced apart along the third direction, and each of the first heat dissipation channels extending along the second direction is in communication with the plurality of first heat dissipation holes spaced apart along the second direction.

In some embodiments, each of the first heat dissipation channels is in communication with one of the second heat dissipation holes; and adjacent two of the first heat dissipation channels along the third direction are in one-to-one communication with two of the second heat dissipation holes disposed in opposite sides of the first region along the second direction.

In some embodiments, another portion of the first heat dissipation channels extend along the third direction and are spaced apart along the second direction, and each of the first heat dissipation channels extending along the third direction is in communication with the plurality of first heat dissipation holes spaced apart along the third direction; and adjacent two of the first heat dissipation channels along the second direction are in one-to-one communication with two of the second heat dissipation holes disposed in opposite sides of the first region along the third direction.

In some embodiments, the heat dissipation structure further includes: a direct flow channel, disposed between the first heat dissipation hole and the first heat dissipation channel, wherein an inner diameter of the direct flow channel is uniformly maintained.

Some embodiments of the present disclosure further provide a semiconductor package device. The semiconductor package device includes: a substrate; a chip, mounted on the substrate; and the heat dissipation structure as described above, covering a surface of the chip facing away from the substrate.

The heat dissipation structure and the semiconductor package device according to the present disclosure achieve improved thermal performance by forming a plurality of heat dissipation holes in the top cover and first heat dissipation channels in communication with the heat dissipation holes. Each of the heat dissipation holes includes an inlet disposed within the top cover and an outlet exposed at the outer surface, wherein the aperture of the outlet is greater than that of the inlet. The first heat dissipation channel extends through the top cover in a direction parallel to the outer surface, such that heated fluid is transferred to the heat dissipation holes via the first heat dissipation channels and then dissipated into the external air through the heat dissipation holes. In this way, the heat dissipation effect of the structure is enhanced by utilizing the Bernoulli principle. Moreover, since the aperture of the outlet of each of the heat dissipation holes is greater than that of the corresponding inlet, the contact area between the heated fluid and the ambient air is increased, such that the heat dissipation performance of the heat dissipation structure is further enhanced.

### BRIEF DESCRIPTION OF THE DRAWINGS

FIG. 1 is a schematic top view of a heat dissipation structure according to some embodiments of the present disclosure;

FIG. 2 is a perspective view taken along a line A-A in FIG. 1;

FIG. 3 is a schematic diagram of heat dissipation principles of a heat dissipation structure according to some embodiments of the present disclosure;

FIG. 4 is a schematic diagram illustrating staggered air intake during heat dissipation of a heat dissipation structure according to some embodiments of the present disclosure;

FIG. 5 is a schematic cross-sectional view of a heat dissipation structure according to some embodiments of the present disclosure; and

FIG. 6 is a schematic cross-sectional view of a heat dissipation structure according to some embodiments of the present disclosure.

### DETAILED DESCRIPTION

Hereinafter, specific embodiments of a heat dissipation structure and a semiconductor package device according to the present disclosure are described in detail with reference to the accompanying drawings.

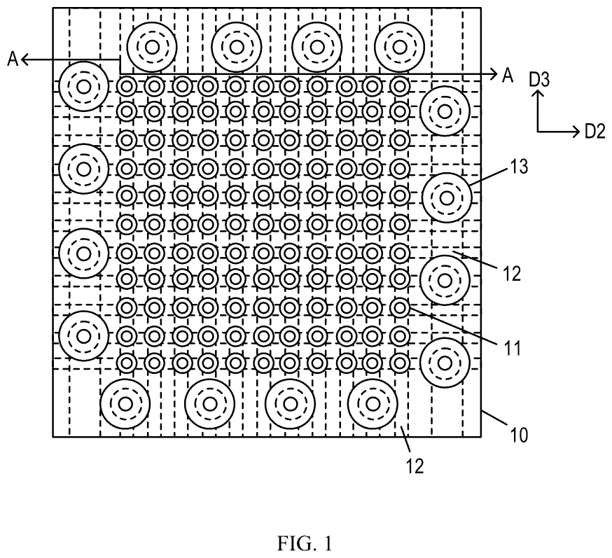

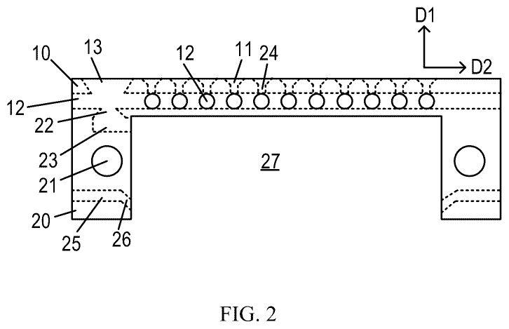

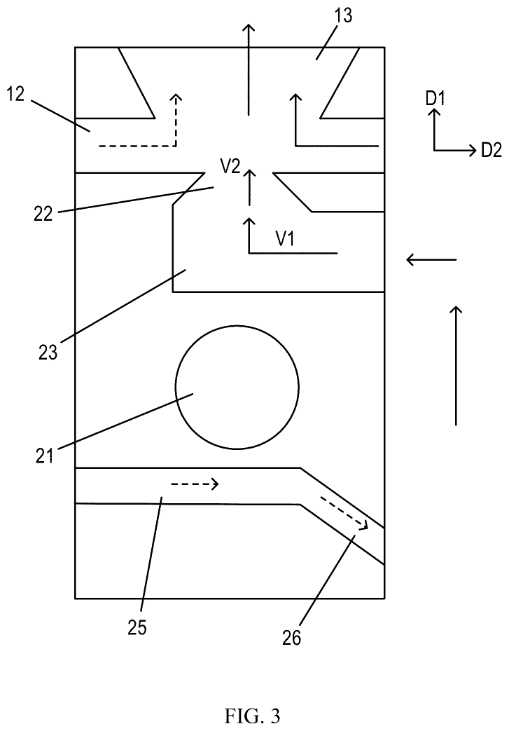

Some embodiments of the present disclosure provide a heat dissipation structure. FIG. 1 is a schematic top view of a heat dissipation structure according to some embodiments of the present disclosure. FIG. 2 is a perspective view taken along a line A-A in FIG. 1. FIG. 3 is a schematic diagram of heat dissipation principles of a heat dissipation structure according to some embodiments of the present disclosure.

As illustrated in FIG. 1 to FIG. 3, the heat dissipation structure includes: a top cover 10, including an inner surface and an outer surface that are oppositely disposed; a heat dissipation hole, at least partially disposed within the top cover 10, wherein the heat dissipation hole includes an inlet disposed within the top cover 10 and an outlet exposed at the outer surface, wherein an aperture of the outlet is greater than an aperture of the inlet; and a heat dissipation channel, including a first heat dissipation channel 12 disposed within the top cover 10 and extending through the top cover 10 in a direction parallel to the outer surface, wherein the first heat dissipation channel 12 is in communication with the inlet and is configured to transfer heated fluid to the inlet.

Specifically, the top cover 10 may be made of a thermally conductive material such as metal. As illustrated in FIG. 1 to FIG. 3, the top cover 10 includes the inner surface and the outer surface that are oppositely disposed along a first direction D1. During heat dissipation of the chip using the heat dissipation structure, the top cover 10 of the heat dissipation structure is mounted on a surface of the chip, with the inner surface of the top cover 10 facing the chip. The heat dissipation hole extends from the outer surface of the top cover 10 into the interior of the top cover 10 along the first direction D1, and do not extend through the top cover 10 along the first direction D1. The inlet and the outlet of the heat dissipation hole are oppositely disposed along the first direction D1. The outlet of the heat dissipation hole is disposed in the outer surface of the top cover 10, and the inlet of the heat dissipation hole is disposed within the interior of the top cover 10. The first heat dissipation channel 12 is disposed within the top cover 10 and extends through the top cover 10 along a second direction D2 and/or a third direction D3. The second direction D2 and the third direction D3 are both parallel to the outer surface of the top cover 10, and are intersected with each other (e.g., intersect perpendicularly or obliquely).

In the heat dissipation structure according to the embodiments, during the operation of the chip, heat generated by the chip increases the temperature of the air surrounding the chip, forming the heated fluid. The heated fluid is transferred to the inlet of the heat dissipation hole through the first heat dissipation channel 12, and then is discharged to the outside through the outlet of the heat dissipation hole. By configuring the aperture of the outlet of the heat dissipation hole to be greater than that of the inlet, the heat dissipation hole assumes an inverted frustoconical shape. In one aspect, this increases the contact area between the heated fluid and the ambient air, such that the heat dissipation performance of the heat dissipation structure is enhanced. In another aspect, as the heated fluid flows from the smaller-aperture inlet to the outlet with the greater aperture, the increase in aperture allows for rapid pressure release of the heated fluid, such that a rapid energy release effect is achieved and the heat dissipation efficiency of the heat dissipation structure is improved. The first heat dissipation channel 12 extends through the top cover 10 in a direction parallel to the outer surface of the top cover, and is in communication with the inlet of the heat dissipation hole. The aperture of the outlet of the heat dissipation hole is configured to be greater than that of the inlet, such that in a case where the heated fluid enters the inlet of the heat dissipation hole from the first heat dissipation channel 12, the flow velocity increases and the pressure of the heated fluid decreases in accordance with the Bernoulli principle, such that the heat dissipation performance of the heat dissipation structure is enhanced. Meanwhile, since the first heat dissipation channel 12 extends through the top cover 10 in a direction parallel to the outer surface of the top cover, a cooling fluid from the external environment (e.g., low-temperature ambient air) enters the interior of the top cover 10 along the first heat dissipation channel 12. That is, the first heat dissipation channel 12 is also capable of delivering the cooling fluid into the top cover 10, such that heat accumulation within the top cover 10 is further reduced and the heat dissipation performance of the heat dissipation structure is further enhanced.

In some embodiments, the top cover 10 includes a first region and a second region peripherally disposed around the first region; and the heat dissipation hole includes:
a plurality of first heat dissipation holes 11 uniformly distributed within the first region of the top cover 10, wherein each of the first heat dissipation holes 11 includes a first inlet disposed within the top cover 10 and a first outlet exposed at the outer surface, wherein an aperture of the first outlet is greater than an aperture of the first inlet.

In some embodiments, the heat dissipation hole further includes: a plurality of second heat dissipation holes 13 disposed within the second region of the top cover, wherein each of the second heat dissipation holes 13 includes a second inlet disposed within the top cover 10 and a second outlet exposed at the outer surface, wherein an aperture of the second outlet is greater than an aperture of the second inlet, and the second heat dissipation holes 13 on opposite sides of the first region are arranged in a staggered manner.

For example, as illustrated in FIG. 1 to FIG. 3, the top cover 10 includes a first region disposed at the center and a second region disposed at the periphery and surrounding the first region. All of the first heat dissipation holes 11 are disposed within the first region, and a plurality of second heat dissipation holes 13 are uniformly distributed in the second region. The inlet of the heat dissipation hole includes the first inlet and the second inlet, and the outlet of the heat dissipation hole includes the first outlet and the second outlet.

The first heat dissipation holes 11 extend from the outer surface of the top cover 10 toward the interior of the top cover 10 along the first direction D1, and do not extend through the top cover 10 along the first direction D1. The first inlets and the first outlets in the first heat dissipation holes 11 are distributed opposite to each other along the first direction D1. The first outlets of the first heat dissipation holes 11 are disposed in the outer surface of the top cover 10, and the first inlets of the first heat dissipation holes 11 are disposed within the top cover 10. In one example, the plurality of first heat dissipation holes 11 are uniformly distributed within the top cover 10 to improve the uniformity of heat dissipation of the heat dissipation structure. The second inlets and the second outlets of the second heat dissipation holes 13 are oppositely distributed along the first direction D1. The second outlets of the second heat dissipation holes 13 are disposed in the outer surface of the top cover 10, and the second inlets of the second heat dissipation holes 13 are disposed within the top cover 10. In one example, the plurality of second heat dissipation holes 13 are uniformly distributed in the second region to further improve the uniformity of heat dissipation of the heat dissipation structure. The second outlets of the second heat dissipation holes 13 have a greater aperture than that of the second inlets, such that the second heat dissipation holes 13 also have an inverted frustoconical shape, thereby further enhancing the heat dissipation performance of the heat dissipation structure. In one example, the second heat dissipation holes 13 disposed in opposite sides of the first region along the second direction D2 are arranged in a staggered manner, and the second heat dissipation holes 13 disposed in opposite sides of the first region along the third direction D3 are also arranged in a staggered manner. Since the second heat dissipation holes 13 are disposed in the edge of the top cover 10 and are also in communication with the first heat dissipation channel 12, by arranging the second heat dissipation holes 13 in opposite sides of the first region in a staggered manner, it is possible to prevent both ends of the same first heat dissipation channel 12 from being communicated to two second heat dissipation holes 13, such that airflow competition within the first heat dissipation channel 12 is prevented. This ensures unidirectional flow of the heated fluid within the first heat dissipation channel 12, such that the heat dissipation performance of the heat dissipation structure is further enhanced.

In some embodiments, the aperture of the second inlet of the second heat dissipation hole 13 is greater than that of the first inlet of the first heat dissipation hole 11, and the aperture of the second outlet of the second heat dissipation hole 13 is greater than that of the first outlet of the first heat dissipation hole 11. This configuration further increases the contact area between the heated fluid and ambient air at the edge of the top cover 10, guiding the heat toward the edge and reducing heat accumulation in the central portion of the top cover, such that the heat dissipation performance of the heat dissipation structure is further enhanced.

In some embodiments, the first heat dissipation channel 12 includes a first opening and a second opening that are oppositely distributed in a first direction D1, wherein the first direction D1 is perpendicular to the outer surface; wherein the first opening is in communication with the second inlet of the second heat dissipation hole 13, and an aperture of the first opening is greater than an aperture of the second opening.

In some embodiments, the heat dissipation channel further includes: a second heat dissipation channel 22, at least partially disposed within the top cover 10, wherein the second heat dissipation channel 22 extends in the first direction and is in communication with the second opening, wherein an inner diameter of the second heat dissipation channel 22 progressively decreases along the first direction D1.

For example, as shown in FIG. 1 to FIG. 3, the first heat dissipation channel 12 in the second region of the top cover 10 includes a first opening and a second opening that are oppositely distributed along the first direction D1. The first opening is in communication with the second inlet of the second heat dissipation hole 13, and the second opening is in communication with the second heat dissipation channel 22. An inner diameter of the second heat dissipation channel 22 progressively decreases along the first direction D1, such that the second heat dissipation channel 22 is shaped as a frustum.

In FIG. 3, the solid-line arrows represent a flow direction of the heated fluid, and the dashed-line arrows represent a flow direction of the cooling fluid. For example, after the heat dissipation structure is mounted onto the chip, the heat generated during operation of the chip causes the surrounding air temperature to rise, and the heated air expands and rises, thereby forming the heated fluid. The heated fluid rises in a direction toward the inner surface of the top cover 10 at a first velocity V1 and enters the second heat dissipation channel 22. In a case where the heated fluid reaches the top of the second heat dissipation channel 22, due to the narrowing of the aperture, the flow velocity of the heated fluid increases. That is, the heated fluid has a second flow velocity V2 at the second opening of the first heat dissipation channel 12. In accordance with the Bernoulli's principle, at the second opening of the first heat dissipation channel 12, the flow velocity of the heated fluid increases, and the pressure decreases, further attracting the hot air from within the first heat dissipation channel 12 (for example, the air in the first heat dissipation channel 12 is heated by the heat generated from the chip during its operation and transferred to the top cover 10). This hot air is then expelled through the second heat dissipation hole 13. When the heated fluid is discharged from the inverted conical structure of the second heat dissipation hole 13, the sudden increase in the diameter of the second heat dissipation hole 13 causes the heated fluid to be released to the external environment at a higher flow velocity. At the same time, because the first heat dissipation channel 12 penetrates the top cover 10 in a direction parallel to the external surface of the top cover, cooling fluid from the external environment (such as low-temperature air from the environment) can enter the top cover 10 through the first heat dissipation channel 12. As the cooling fluid flows through the first heat dissipation channel 12 toward the second heat dissipation hole 13, the heated fluid within the second heat dissipation hole 13 may be cooled, preventing heat buildup on the external surface of the top cover, such that the heat dissipation performance of the heat dissipation structure is further improved.

In some embodiments, the heat dissipation structure further includes: a side plate 20, connected to an end portion of the top cover 10, and connected to the top cover 10 either perpendicularly or at an inclined angle, wherein the side plate 20 and the top cover 10 together form an accommodation chamber 27; wherein the heat dissipation channel further includes a third heat dissipation channel 23 disposed within the side plate 20, wherein the third heat dissipation channel 23 includes a third opening and a fourth opening, wherein the third opening is in communication with the second heat dissipation channel 22, and the fourth opening is disposed in a surface of the side plate 20 facing the accommodation chamber 27.

Specifically, by configuring the side surface 20, the contact area between the heat dissipation structure and the external air may be further increased, such that the heat dissipation effect of the heat dissipation structure is further enhanced. One end of the third heat dissipation channel 23 is in communication with the second heat dissipation channel 22, and the other end of the third heat dissipation channel 23 faces the accommodation chamber 27. The accommodation chamber 27 is configured to house the chip, and the heated fluid generated during the operation of the chip flows through the third heat dissipation channel 23 into the second heat dissipation channel 22, such that the heated fluid is rapidly directed to the external environment.

In some embodiments, the heat dissipation channel further includes: a fourth heat dissipation channel 21, disposed within the side plate 20 and extending through the side plate 20 in a direction parallel to the outer surface; wherein in the first direction D1, the third heat dissipation channel 23 is positioned above the fourth heat dissipation channel 21.

For example, as illustrated in FIG. 1 to FIG. 3, the fourth heat dissipation channel 21 disposed within the side plate 20 extends along the third direction D3 and extends through the side plate 20 along the third direction D3. The fourth heat dissipation channel 21 is configured to discharge heat, such that the heat dissipation effect of the heat dissipation structure is further enhanced.

In some embodiments, the heat dissipation channel further includes: a fifth heat dissipation channel, disposed within the side plate 20 and extending through the side plate 20 in a direction parallel to the outer surface; wherein in the first direction D1, the fifth heat dissipation channel is positioned below the fourth heat dissipation channel 21.

For example, as illustrated in FIG. 1 to FIG. 3, the fifth heat dissipation channel disposed within the side plate 20 extends along the second direction D2 and extends through the side plate 20 along the second direction D2.

In some embodiments, the fifth heat dissipation channel includes a cooling fluid inlet and a cooling fluid outlet that are oppositely distributed, wherein the cooling fluid inlet is disposed in a surface of the side plate 20 facing away from the accommodation chamber 27, and the cooling fluid outlet is disposed in a surface of the side plate 20 facing toward the accommodation chamber 27; wherein in the first direction D1, the cooling fluid inlet is positioned above the cooling fluid outlet.

In some embodiments, the fifth heat dissipation channel includes a first portion 25 extending in a direction parallel to the outer surface and a second portion 26 that is in inclined communication with the first portion 25; wherein the cooling fluid inlet is disposed at an end of the first portion 25v facing away from the second portion 26, and the cooling fluid outlet is disposed at an end of the second portion 26 facing away from the first portion 25.

Specifically, the fifth heat dissipation channel is disposed below the fourth heat dissipation channel 21 along the first direction D1. After the heated fluid is discharged through the first heat dissipation hole 11 and the second heat dissipation hole 13, low-temperature air and other cooling fluids enter the accommodation chamber 27 through the fifth heat dissipation channel, to replenish the air and other fluids within the accommodation chamber 27. By configuring the first portion 25 and the second portion 26 in the fifth heat dissipation channel, which are communicated in an inclined manner, the cooling fluid flows more smoothly from the first portion 25 to the second portion 26, such that the effects of filling the lower part of the accommodation chamber 27 and cooling the interior of the accommodation chamber 27 are achieved.

FIG. 5 is a schematic cross-sectional view of a heat dissipation structure according to some embodiments of the present disclosure. In some other embodiments, the heat dissipation structure may also be configured without the side plate 20, in order to further decrease the size of the heat dissipation structure while simplifying the heat dissipation structure.

In some embodiments, the plurality of the first heat dissipation holes 11 are arranged in an array along a second direction D2 and a third direction D3, wherein the second direction D2 and the third direction D3 are parallel to the outer surface, and the second direction D2 is intersected with the third direction D3; wherein at least a portion of the first heat dissipation channels 12 extend along the second direction D2 and are spaced apart along the third direction D3, and each of the first heat dissipation channels 12 extending along the second direction D2 is in communication with the plurality of first heat dissipation holes 11 spaced apart along the second direction D2.

In some embodiments, each of the first heat dissipation channels 12 is in communication with one of the second heat dissipation holes; 11 and adjacent two of the first heat dissipation channels 12 along the third direction D3 are in one-to-one communication with two of the second heat dissipation holes 13 disposed in opposite sides of the first region along the second direction D2.

In some embodiments, another portion of the first heat dissipation channels 12 extend along the third direction D3 and are spaced apart along the second direction D2, and each of the first heat dissipation channels 12 extending along the third direction D3 is in communication with the plurality of first heat dissipation holes 11 spaced apart along the third direction D3; and adjacent two of the first heat dissipation channels 12 along the second direction D2 are in one-to-one communication with two of the second heat dissipation holes 13 disposed in opposite sides of the first region along the third direction D3.

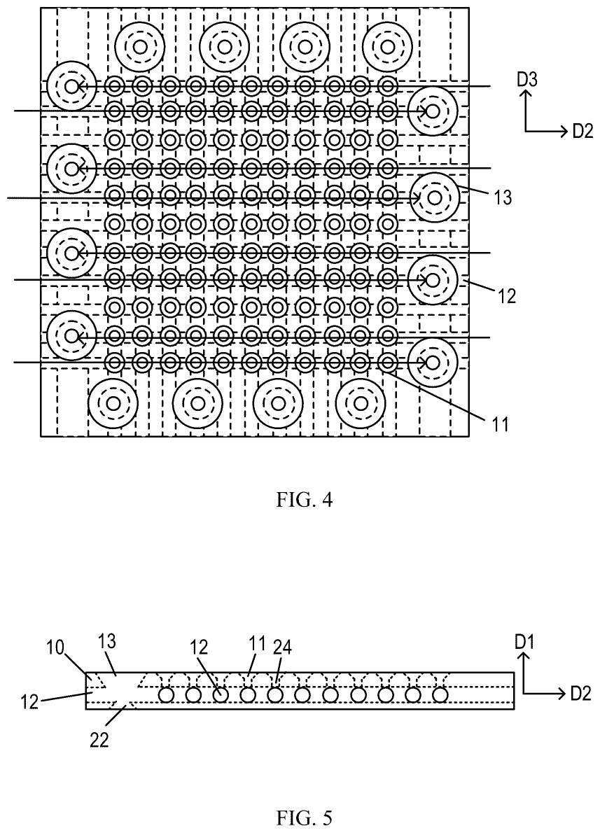

FIG. 4 is a schematic diagram illustrating staggered air intake during heat dissipation of a heat dissipation structure according to some embodiments of the present disclosure. The arrows in FIG. 4 indicate a flow direction of the heated fluid within the first heat dissipation channel 12. Specifically, as illustrated in FIG. 1 FIG. 4, the second heat dissipation holes 13 disposed in both sides of the first region along the second direction D2 are staggered, and the second heat dissipation holes 13 disposed in both sides of the first region along the third direction D3 are also staggered, thereby forming a staggered air intake. For example, since each of the first heat dissipation channels 12 extending along the second direction D2 is only in communication with one second heat dissipation hole 13 and a row of first heat dissipation holes 11 spaced along the second direction D2, the heated fluid in each of the first heat dissipation channels 12 flows toward the second heat dissipation hole 13 disposed at the end of the channel. This arrangement prevents air intake competition within the same first heat dissipation channel 12, such that the heat dissipation performance of the structure is further enhanced.

In some embodiments, the heat dissipation structure further includes: a direct flow channel 24 disposed between the first heat dissipation hole 11 and the first heat dissipation channel 12, wherein an inner diameter of the direct flow channel 24 is smaller than that of the first heat dissipation channel 12 to achieve the purpose of reducing the flow area and increasing the flow velocity of the heated fluid coming from the first heat dissipation channel 12. When the accelerated heated fluid passes through the direct flow channel 24 and reaches the first heat dissipation hole 11, the flow area increases, which can achieve the effect of rapid energy release and heat dissipation. Moreover, there is a certain moving airflow, which enhances the gas movement on the top cover 10 and further improves the heat dissipation effect.

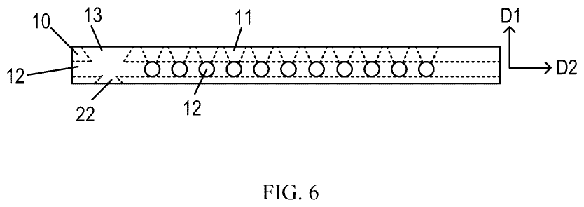

FIG. 6 is a schematic cross-sectional view of a heat dissipation structure according to some embodiments of the present disclosure. In some other embodiments, as illustrated in FIG. 6, the heat dissipation structure may also be configured without the direct flow channel 24, in order to further increase the heat dissipation rate of the heat dissipation structure while simplifying the manufacturing process of the heat dissipation structure.

Some embodiments of the present disclosure further provide a semiconductor package device. The semiconductor package device includes: a substrate; a chip, mounted on the substrate; and a heat dissipation structure as described above, covering a surface of the chip facing away from the substrate, wherein reference may be made to FIG. 1 to FIG. 6 for the schematic view of the heat dissipation structure.

The heat dissipation structure and the semiconductor package device according to the embodiments of the present disclosure achieve improved thermal performance by forming a plurality of heat dissipation holes in the top cover and first heat dissipation channels in communication with the heat dissipation holes. Each of the heat dissipation holes includes an inlet disposed within the top cover and an outlet exposed at the outer surface, wherein the aperture of the outlet is greater than that of the inlet. The first heat dissipation channel extends through the top cover in a direction parallel to the outer surface, such that heated fluid is transferred to the heat dissipation holes via the first heat dissipation channels and then dissipated into the external air through the heat dissipation holes. In this way, the heat dissipation effect of the structure is enhanced by utilizing the Bernoulli principle. Moreover, since the aperture of the outlet of each of the heat dissipation holes is greater than that of the corresponding inlet, the contact area between the heated fluid and the ambient air is increased, such that the heat dissipation performance of the heat dissipation structure is further enhanced.

Described above are preferred embodiments of the present disclosure. It should be noted that persons of ordinary skill in the art may derive other improvements or polishments without departing from the principles of the present disclosure. Such improvements and polishments shall be deemed as falling within the protection scope of the present disclosure.

What is claimed is:

1. A heat dissipation structure, comprising:
a top cover, comprising an inner surface and an outer surface that are oppositely disposed;
a heat dissipation hole, at least partially disposed within the top cover, the heat dissipation hole comprising an inlet disposed within the top cover and an outlet exposed at the outer surface, wherein an aperture of the outlet is greater than an aperture of the inlet; and
a heat dissipation channel, comprising a first heat dissipation channel disposed within the top cover and extending through the top cover in a direction parallel to the outer surface, wherein the first heat dissipation channel is in communication with the inlet and is configured to transfer heated fluid to the inlet.

2. The heat dissipation structure according to claim 1, wherein the top cover comprises a first region and a second region peripherally distributed around the first region; and the heat dissipation hole comprises:
a plurality of first heat dissipation holes uniformly distributed within the first region of the top cover, each of the first heat dissipation holes comprising a first inlet disposed within the top cover and a first outlet exposed at the outer surface, wherein an aperture of the first outlet is greater than an aperture of the first inlet.

3. The heat dissipation structure according to claim 2, wherein the heat dissipation hole further comprises:
a plurality of second heat dissipation holes disposed within the second region of the top cover, each of the second heat dissipation holes comprising a second inlet disposed within the top cover and a second outlet exposed at the outer surface, wherein an aperture of the second outlet is greater than an aperture of the second inlet, and the second heat dissipation holes on opposite sides of the first region are arranged in a staggered manner.

4. The heat dissipation structure according to claim 3, wherein the aperture of the second inlet of the second heat dissipation hole is greater than the aperture of the first inlet of the first heat dissipation hole, and the aperture of the second outlet of the second heat dissipation hole is greater than the aperture of the first outlet of the first heat dissipation hole.

5. The heat dissipation structure according to claim 3, wherein the first heat dissipation channel comprises a first opening and a second opening that are oppositely distributed in a first direction, the first direction being perpendicular to the outer surface;
wherein the first opening is in communication with the second inlet of the second heat dissipation hole, and an aperture of the first opening is greater than an aperture of the second opening.

6. The heat dissipation structure according to claim 5, wherein the heat dissipation channel further comprises:
a second heat dissipation channel, at least partially disposed within the top cover, the second heat dissipation channel extending in the first direction and being in communication with the second opening, wherein an inner diameter of the second heat dissipation channel progressively decreases along the first direction.

7. The heat dissipation structure according to claim 6, further comprising:
a side plate, connected to an end portion of the top cover, and connected to the top cover either perpendicularly or at an inclined angle, wherein the side plate and the top cover together form an accommodation chamber;
wherein the heat dissipation channel further comprises a third heat dissipation channel disposed within the side plate, the third heat dissipation channel comprising a third opening and a fourth opening, wherein the third opening is in communication with the second heat dissipation channel, and the fourth opening is disposed in a surface of the side plate facing the accommodation chamber.

8. The heat dissipation structure according to claim 7, wherein the heat dissipation channel further comprises:
a fourth heat dissipation channel, disposed within the side plate and extending through the side plate in a direction parallel to the outer surface;
wherein in the first direction, the third heat dissipation channel is positioned above the fourth heat dissipation channel.

9. The heat dissipation structure according to claim 8, wherein the heat dissipation channel further comprises:
a fifth heat dissipation channel, disposed within the side plate and extending through the side plate in a direction parallel to the outer surface;
wherein in the first direction, the fifth heat dissipation channel is positioned below the fourth heat dissipation channel.

10. The heat dissipation structure according to claim 9, wherein the fifth heat dissipation channel comprises a cooling fluid inlet and a cooling fluid outlet that are oppositely distributed, the cooling fluid inlet being disposed in a surface of the side plate facing away from the accommodation chamber, and the cooling fluid outlet being disposed in a surface of the side plate facing toward the accommodation chamber;
wherein in the first direction, the cooling fluid inlet is positioned above the cooling fluid outlet.

11. The heat dissipation structure according to claim 10, wherein the fifth heat dissipation channel comprises a first portion extending in a direction parallel to the outer surface and a second portion that is in inclined communication with the first portion;
wherein the cooling fluid inlet is disposed at an end of the first portion facing away from the second portion, and the cooling fluid outlet is disposed at an end of the second portion facing away from the first portion.

12. The heat dissipation structure according to claim 3, wherein the plurality of the first heat dissipation holes are arranged in an array along a second direction and a third direction, the second direction and the third direction being parallel to the outer surface, and the second direction being intersected with the third direction;
wherein at least a portion of the first heat dissipation channels extend along the second direction and are spaced apart along the third direction, and each of the first heat dissipation channels extending along the second direction is in communication with the plurality of first heat dissipation holes spaced apart along the second direction.

13. The heat dissipation structure according to claim 12, wherein each of the first heat dissipation channels is in communication with one of the second heat dissipation holes; and
adjacent two of the first heat dissipation channels along the third direction are in one-to-one communication with two of the second heat dissipation holes disposed in opposite sides of the first region along the second direction.

14. The heat dissipation structure according to claim 13, wherein another portion of the first heat dissipation channels extend along the third direction and are spaced apart along the second direction, and each of the first heat dissipation channels extending along the third direction is in communication with the plurality of first heat dissipation holes spaced apart along the third direction; and
adjacent two of the first heat dissipation channels along the second direction are in one-to-one communication with two of the second heat dissipation holes disposed in opposite sides of the first region along the third direction.

15. The heat dissipation structure according to claim 2, further comprising:
a direct flow channel, disposed between the first heat dissipation hole and the first heat dissipation channel, wherein an inner diameter of the direct flow channel is uniformly maintained.

16. A semiconductor package structure, comprising:
a substrate;
a chip, mounted on the substrate; and
the heat dissipation structure as defined in claim 1, covering a surface of the chip facing away from the substrate.
